(19) United States
(12) Patent Application Publication
(10) Pub. No.: US 2008/0222491 A1
(43) Pub. Date: Sep. 11, 2008

(54) FLASH MEMORY SYSTEM FOR IMPROVING READ PERFORMANCE AND READ METHOD THEREOF

(76) Inventors: Chang-Duck Lee, Seoul (KR); Seok-Won Heo, Seoul (KR); Si-Yung Park, Seoul (KR); Dong-Ryoul Lee, Incheon (KR)

Correspondence Address: F. CHAU & ASSOCIATES, LLC, 130 WOODBURY ROAD, WOODBURY, NY, 11797, US

(21) Appl. No.: 11/694,237

(22) Filed: Mar. 30, 2007

(30) Foreign Application Priority Data
Feb. 7, 2007 (KR) 2007-12822

(51) Int. Cl. G11C 29/00

(52) U.S. Cl. 714/763

(57) ABSTRACT

A method of transmitting data from a flash memory device to a host includes: detecting whether the data includes an error or not; performing an error correction operation for correcting the data having the error when the error exists in the data; and sequentially storing the data having the error and a plurality of subsequent read data without outputting. The storing of the data is performed during the performing of the error correction operation.

### CROSS-REFERENCE TO RELATED APPLICATION

This patent application claims priority under 35 U.S.C. 119 of Korean Patent Application No. 2007-12822, filed on Feb. 7, 2007, the entire contents of which are hereby incorporated by reference.

### BACKGROUND OF THE INVENTION

The present disclosure relates to a semiconductor memory device and, more particularly, to a read method of a non-volatile memory device.

A semiconductor memory device is generally categorized as either a volatile or non-volatile memory device. Volatile memory devices are classified into dynamic random access memories (DRAMs) and static random, access memories (SRAMs). A volatile semiconductor device loses its stored data when a power supply is removed, while a non-volatile memory device retains its stored data even when no power supply is applied. Thus, non-volatile memories are widely used to store data in applications whose data retention is required regardless of the presence of a power supply. Examples of non-volatile memories are mask read-only memories (MROMs). programmable read-only memories (PROMs), erasable programmable read-only memories (EPROMs), and electrically erasable programmable read-only memories (EEPROMs).

In the MROM, PROM, and EPROM kinds of memories, it is not an easy task for a general user to update memory contents, because erase and write operations are not simple enough within a memory system itself. On the other hand, since an EEPROM is capable of electrically erasing and writing its contents, it is widely used in system programming that requires a continuous update, or in an auxiliary memory device. More specifically, a flash EEPROM has a higher degree of integration compared to a conventional EEPROM and, thus, can be used as a high-capacity auxiliary memory device. A NAND-type flash EEPROM (hereinafter, referred to as a NAND flash memory) has an even higher degree of integration compared to other flash EEPROMs.

As a higher and higher degree of integration has been increasingly demanded for memory devices, multi-bit memory devices have become widely used for storing multi-bit data in one memory cell. Memory cells of a multi-bit flash memory device need to be formed having dense intervals between threshold voltage distributions. To control a dense threshold voltage distribution, the multi-bit flash memory device requires an accurate control operation, as well as time for a control operation during a program operation. This control method deteriorates a program speed, however, such that its efficiency decreases. Accordingly, to achieve the maximum performance with a limited resource, the multi-bit flash memory device generally controls a read operation. While performing the read operation, a memory that provides an interface between a host and a flash memory device corrects errors that are contained in data read from the flash memory device.

An error correction code block (hereinafter, referred to as an ECC block) in a memory controller detects and corrects errors that are contained in the read data. As more bits are stored in one memory cell, the error occurrence probability increases. Accordingly; as the degree of integration increases, a high performance of an ECC block is required. An error correction operation demands a relatively long time to correct the errors in the read data. Accordingly, in spite of the error correction operation, a high-speed ECC block is required to provide the read data having no errors to the host without delay. An error correction method supporting a high-speed error correction operation is called an On-the-fly method. To provide a memory controller supporting the On-the-fly method, a high-performance ECC block having a high processing speed is required.

FIG. 1 is a block diagram of a memory controller 120 performing an error correction operation according to an On-the-fly method. Referring to FIG. 1, a high performance ECC block 122 in the memory controller 120 receives read data RD_Data and then detects errors at high speed. The ECC block 122 generates an error vector Err to correct the errors at high speed in the error-detected data. The generated error vector Err merges (e.g., an XOR operation) with the read data having the errors to correct its errors. A more detailed description will be set forth as follows.

The read data RD_Data from a flash memory device 110 pass through two paths. The read data RD_Data continuously passes through a data path \textcircled{1} regardless of whether an error is present. The data path \textcircled{1} includes a flash memory interface 121 and a buffer 123. The data path \textcircled{1}, however, does not include the ECC block 122. The data path \textcircled{1} for an XOR operation that performs an error correction operation, delivers read data RD_A at the output of the butter 123.

A data path \textcircled{2} includes the memory interface 121. More specifically, the data path \textcircled{2} includes the ECC block 122 included in the memory interface 121. The read data RD_Data from the flash memory device 110 is delivered into the ECC block 122 to detect errors. The ECC block 122 generates a syndrome to detect errors in the read data RD_Data. According to the syndrome, the ECC block 122 detects the errors in the read data RD_Data. When there are errors, the ECC 122 performs an error correction operation to generate an error vector Err that can correct the errors. According to the error connection operation, the ECC block 122 generates the error vector Err corresponding to the read data RD_A in the data path \textcircled{1}. The generated error vector Err merges (for example, performs an XOR operation) with the read data RD_A, thereby correcting the errors.

Here, the buffer 123 simply buffers data. For example, the buffer 123 can temporarily store output data in units of a page (512 byte) or units of a sector. The buffer 123 is made of an SRAM.

FIG. 2 is a timing diagram illustrating an error correction operation of the system shown in FIG. 1. Referring to FIG. 2, the read data RD_Data from the flash memory device 110 passes through two paths for error correction in the memory controller 120. The read data RD_Data are delivered through the data path \textcircled{1} having the buffer 123, and then becomes the read data RD-A. The data path \textcircled{2} passing through the ECC block 122, which performs the error detection and correction, delivers an error vector Err. Assuming that the read data B include errors, the data B* having errors are represented as a shaded data B*. The error vector Err of the data B* outputted from the ECC block 122 is represented as e_{B}. The error vector e_{B} is generated by using a computation during an error correction time tECC after the data B* is delivered into the ECC block 122. After the error correction time tECC, the error vector e_{B} merges with the data B* for an XOR logic operation (that is, an exclusive OR). Accordingly, a host can receive a normal data B with a corrected error, that is, read data RD_Host. At this point, the error correction time tECC must be short enough for the data B to be received without delay in the host,

In the memory controller 120 performing tire above error correction operation, the data path \textcircled{1} should be synchronized with the data path \textcircled{2}. To accomplish this, the ECC block 122 needs to perform an error correction operation at high speed, because it typically requires a relatively long time. The error correction for the above-described data path synchronization is performed by an error correction operation according to the On-the-fly method. For the high-speed and high-performance error correction operation, an expensive, high-performance ECC block 122 is required. As the number of devices in the ECC block 122 increases, the size of the memory controller 120 becomes larger. As the mobile phone trend becomes more and more popular, the memory controller needs to be slim and light Accordingly, the ECC block that does not support an On-the-fly method is widely used due to its decreased size. When considering this technical background, it is seen that a method of improving an error correction performance and a read speed without increasing the size of the ECC block is required.

### SUMMARY OF THE INVENTION

Exemplary embodiments of the present invention provide a data reading method and a device that minimize data delay in a memory controller including a low-performance error correction block.

Exemplary embodiments of the present invention provide methods of transmitting data from a flash memory device to a host, the methods including: detecting whether the data include an error or not; performing an error correction operation for correcting the data having the error when the error exists in the data; and sequentially storing the data having the error and a plurality of subsequent read data without outputting. The storing of the data is performed during the performing of the error correction operation.

In some exemplary embodiments, the buffer stores the data having the error and the plurality of subsequent read data by using a FIFO method during the storing of the data.

In other exemplary embodiments, the buffer is a write verify buffer used for program verification when the data is programmed into the flash memory device.

In some exemplary embodiments, the error correction operation is not performed when there is no error in the data during the operation of detecting errors.

In exemplar) embodiments, the buffer does not store the data therein but outputs the data.

In other exemplar) embodiments, the method further includes sequentially outputting the stored data having the error and the plurality of subsequent read data in the buffer as soon as the performing of the error correction operation is completed.

In further exemplary embodiments, the error in the data is removed by an error correction vector generated by the error correction operation.

In exemplary embodiments, the error correction operation does not support an On-the-fly method.

According to exemplary embodiments of the present invention, memory systems include: a flash memory device; and a memory controller receiving read data from the flash memory device to detect whether the read data includes an error or not during a read operation; storing the read data having the error and a plurality of subsequent read data therein during an error correction time therefor when the read data includes the error; and removing the error in the read data by using an error vector generated during the error correction time.

In some exemplary embodiments, the memory controller includes a buffer storing the read data having the error and the plurality of subsequent read data by using a FIFO (First In-First Out) method during the error correction time.

In other exemplary embodiments, the buffer outputs the data having the error first according to an inputted priority when the error correction time is completed.

In still other exemplary embodiments, the buffer is a write verify buffer storing program data and re-supplying the program data when a program failure occurs during a program operation of the flash memory device.

According to exemplary embodiments, the memory controller includes an error correction block detecting the read data to determine whether the read data includes an error or not, and generating an error vector for correcting the error in the read data.

In exemplary embodiments, the error vector merges with the read data having the error to remove the error, the read data having been outputted from the buffer.

In further exemplary embodiments, the memory controller has a data processing speed faster than a read data transmission speed of the flash memory device.

In still further exemplary embodiments, the memory controller does not support an error correction operation using an On-the-fly method.

According to exemplary embodiments of the present invention, memory systems include: a flash memory device; an error correction block detecting an error in read data of the flash memory device, and generating an error vector to correct the error in the read data; a buffer selecting one of a first buffering mode and a second buffering mode, the first buffering mode receiving and outputting the read data simultaneously, the second buffering mode storing the read data by using a FIFO method without outputting; and a control unit controlling the buffer to store the read data according to one of the first buffering mode and the second buffering mode in response to an error detection result from the error correction, block during a read operation.

In some exemplary embodiments, the control unit controls the buffer to store the read data according to the second buffering mode in response to an error detection result from the error correction block.

In exemplary embodiments, the control unit controls the buffer to store the read data according to the first buffering mode in response to a non-error detection result from the error correction block.

In exemplary embodiments, when the read data is stored in the buffer according to the second buffering mode, the buffer stores the read data having the error and subsequent read data by using a FIFO method without outputting while the error correction block performs an error correction operation.

In some exemplary embodiments, the second buffering mode sequentially outputs the read data having the error first and the subsequent read data therein when the error correction operation is completed.

According to exemplary embodiments, the second buffering mode sequentially outputs the read data having the error first and the subsequent read data therein when the error correction operation is completed, and also outputs the read data at a speed faster than a transmission speed from the flash memory device.

Exemplary embodiments provide an error correction time for generating the error vector of the error correction block that is longer than one clock during which time the buffer outputs the read data.

In some exemplary embodiments, the buffer has a capacity sufficient for storing the read data having the error and the subsequent read data by using a FIFO method during the error correction time.

In further exemplary embodiments, the buffer is a write verify buffer storing program data and re-supplying the program data when a program failure occurs during a program operation of the flash memory device.

Exemplary embodiments provide a memory system that further includes an operator merging the error vector from the error correction block with the read data having the error from the buffer to remove the error.

According to exemplary embodiments, the operator performs an XOR operation with the error vector and the read data having the error.

In exemplary embodiments, the flash memory device is a NAND-type flash memory.

### BRIEF DESCRIPTION OF THE FIGURES

Exemplary embodiments of the present invention will be understood in more detail from the following descriptions taken in conjunction with the attached drawings. In the Figures:

FIG. 1 is a block diagram of a memory system with an ECC block supporting an On-the-fly method:

FIG. 2 is a timing diagram illustrating an error correction operation according to an On-the-fly method;

FIG. 3 is a block diagram of a read method according to an exemplary embodiment of the present invention;

FIG. 4 is a block diagram of a write verify buffer and an error correction block used in the system of FIG. 3;

FIGS. 5A, 5B, and 5C are block diagrams illustrating a FIFO operation of a write verify buffer while detecting data with an error;

FIG. 6A is a timing diagram of a read operation when there is no error in the data;

FIG. 6B illustrates a problem of a conventional read operation without an On-the-fly method;

FIG. 6C is a timing diagram of a read operation when there is an error according to an exemplary embodiment of the present invention.

FIG. 7A is a timing diagram illustrating a read operation when there is no error according to an exemplary embodiment of the present invention;

FIG. 7B is illustrates a problem of a conventional read operation without an On-the-fly method; and

FIG. 7C is a timing diagram of a read operation when there is an error according to an exemplary embodiment of the present invention.

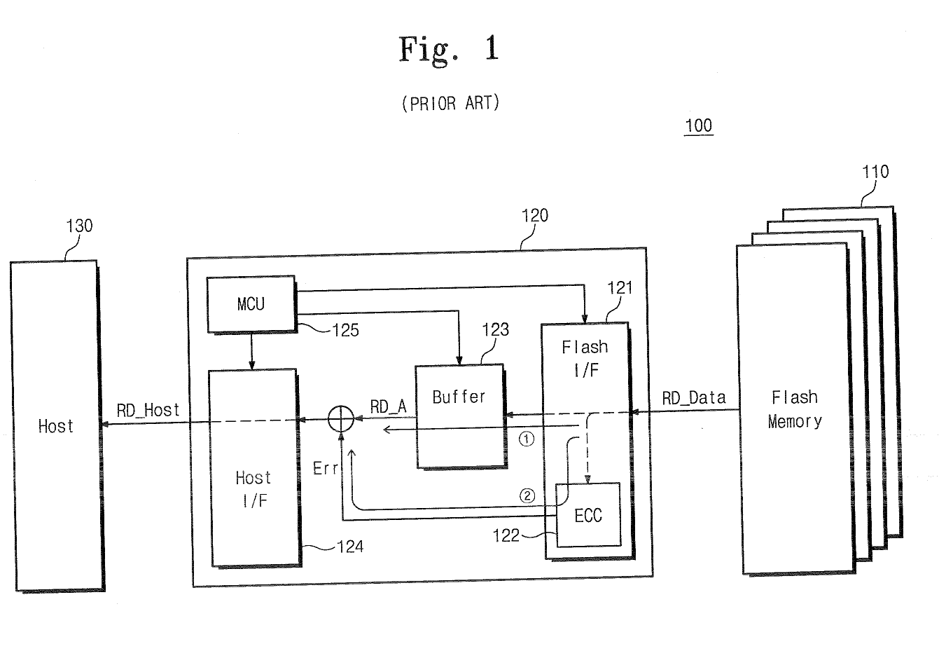

### DETAILED DESCRIPTION OF EXEMPLARY EMBODIMENTS

Exemplary embodiments of the present invention will be described below in more detail with reference to the accompanying drawings. The present invention may, however; be embodied in different forms and should not be constructed as limited to the exemplary embodiments set forth herein. Rather, these exemplary embodiments are provided so that this disclosure will be thorough and complete, and will fully convey the scope of the present invention to those skilled in the art. Like reference numerals refer to like elements throughout.

Hereinafter, a NAND type Hash memory device is used to explain features and functions of exemplary embodiments of the present invention. Those with ordinary skill in the art, however, easily understand other advantages and performance of the exemplary embodiments of the present invention according to the following descriptions. The present invention also can be embodied or applied through other exemplary embodiments. The above-disclosed subject matter is to be considered illustrative, and not restrictive, and the appended claims are intended to cover all such modifications, enhancements, and other exemplary embodiments, which fall within the true spirit and scope of the present invention.

Moreover, an error correcting operation using an on-the-fly method is described in relation to the exemplary embodiments of the present invention. The error correcting operation using the on-the-fly method is an error correction method that can provide data at a speed that is identical to that used when data with an error is delivered. The error correcting operation using the on-the-fly method is a high-speed and high-performance correcting method in which time consumed for error correcting does not delay data production. Accordingly, a large size error correction circuit is required. Hereinafter, a more detailed description will be made with reference to the drawings.

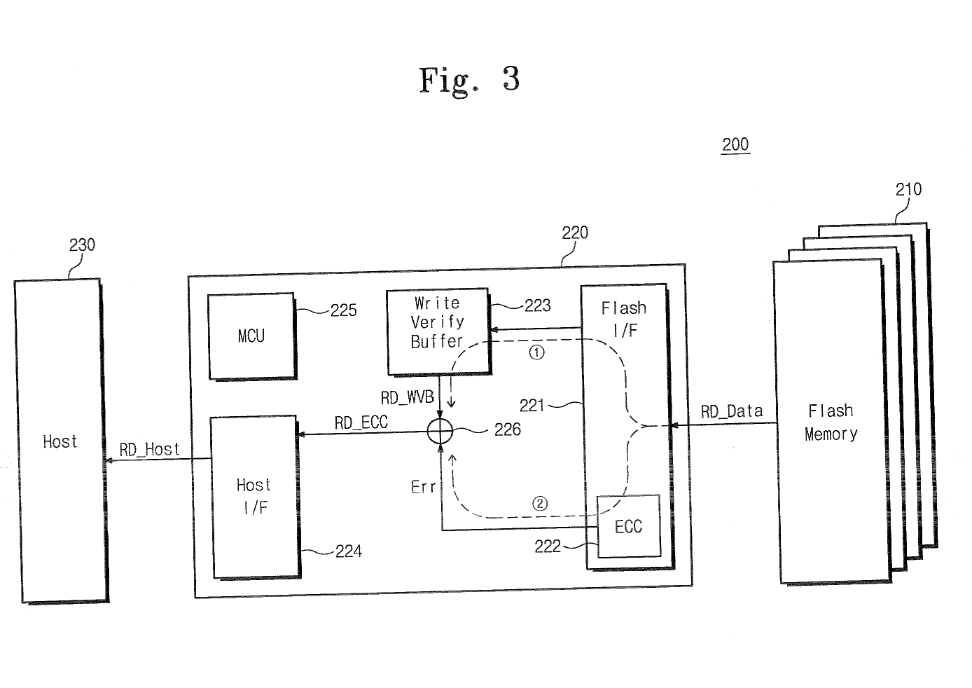

FIG. 3 is a block diagram illustrating a read system for a flash memory device. Referring to FIG. 3, a memory controller 220 does not support an error correction function using an On-the-fly method while reading data from a flash memory device 210. The memory controller 220, however, uses a write verify buffer 223 as a First In-First Out (FIFO) buffer during a reading operation. When detecting errors in read data RD_Data, the write verify buffer 223 sequentially stores data having errors and the subsequent read data RD_Data. The write verify buffer 223 stores the data having errors and the subsequent read data RD_Data therein until an error correction operation is completed. When the error correction operation is completed and an error vector Err is generated, the write verify buffer 223 allows an XOR gate 226 to output data of the result of the merged error vector Err and data having errors. A more detailed description is set forth as follows.

In response to a read or write request (not shown) from the host 230, the memory controller 220 controls the flash memory device 210. The memory controller 220 converts access data from the host 230 into an address and a control signal, which have formats appropriate for the flash memory device 210. During a read operation, the memory controller 220 reads the data stored in tire flash memory device 210 according to the address and the control signal. The memory controller 220 has a flash transition layer (FTL) function that maps a logical address from the host 230 into a physical address of the flash memory device 210. Additionally, the FTL supports a garbage collection operation that collects effective data scattered in each block of the flash memory device 210 so as to fill one block. When the host 230 requests a write operation for a logical block number whose block includes already written data, the FTL writes the data from the host 230 into another location, and then nullifies the already existing data of the requested logical block number. This operation in the FTL is called a garbage collection. The performance of the flash memory depends on how fast this operation can be performed. More specifically, as tire usage time of the system becomes longer, an amount of stored data increases and the number of reserved blocks decreases. Thus, the performance of the garbage collection becomes important. The memory controller 220 counts the number of erasures to arrive at uniform deterioration of the flash memory device 210. Sequencing for the above counting operation is called wear leveling. The FTL of the memory controller 220 must be performed continuously. In addition to these operations, the memory controller 220 does not support an error correction function using an On-the-fly method, but uses the write verify buffer 223 as a read FIFO buffer during a read operation. The structure and the error correction method of the memory controller 220 can solve a data delay problem that occurs during an error correction operation. Components and operations in the memory controller 220 are described in more detail as follows.

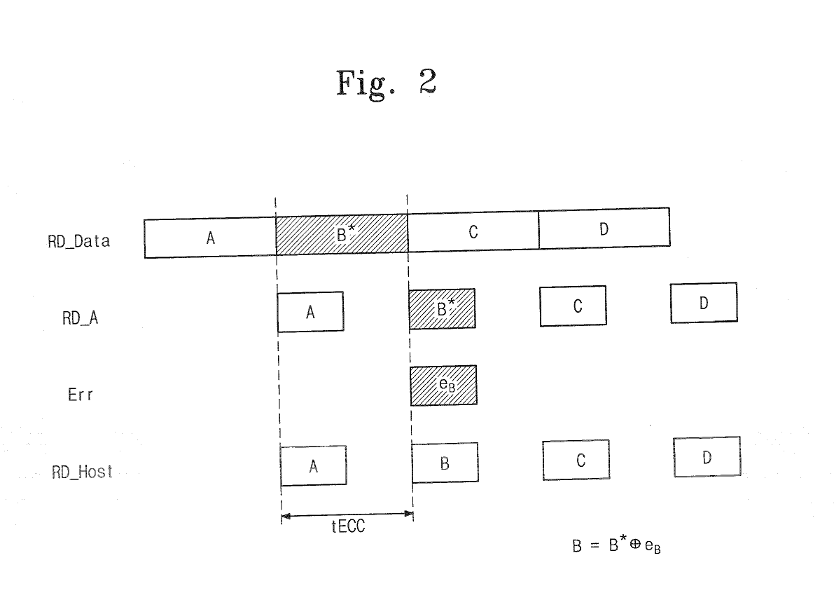

A flash interface 221 is connected to the flash memory device 210, and provides interfacing between the memory controller 220 and the flash memory device 210. The flash interface 221 includes an ECC block 222. The ECC block 222 detects and corrects errors of read data RD_Data read from the flash memory device 210. The ECC block 222 receives the read data RD_Data in real-time and determines whether errors exist in the data or not. To accomplish this, the ECC block 222 reads parity data with error information from a spare region of the flash memory device 210. Referring to the error information, the ECC block 222 calculates an error syndrome. When there are errors in the read data RD_Data identified by the syndrome, and the ECC block 222 generates an error vector Err for correcting the errors. The time consumed for calculating the error vector Err is included in an error correction time tECC shown in FIG. 2. The data path including the ECC block 222 constitutes a data path \textcircled{2}.

The read data RD_Data is delivered into the data path \textcircled{1}. The data path \textcircled{1} only delivers the data without error detection and correction operations. More specifically, the read data RD Data delivered into the write verify buffer 223 are not stored in the write verify buffer 223 when there is no error. When there are errors in the ECC block 222, however, the write verify buffer 223 sequentially stores the read data having errors and the subsequently read data therein without outputting. The write verify buffer 223 stores the read data using the FIFO method until the error vector Err is calculated for error correction. The memory control unit (MCU) 225 receives a flag signal (not shown), which notifies data correction completion, from the ECC block 222, and then controls the write verify buffer 223 for outputting the accumulated data. The memory control unit 225 controls the write verify buffer 223 to synchronize data having errors and the subsequent accumulated data in the write verify buffer 223 with the error vector Err from the ECC block 222 for outputting. At this point, the write verify buffer 223 outputs the buffering data at the maximum speed according to an input order. When the outputting of the accumulated buffering data is completed, the write verify buffer 223 performs a general buffer operation that immediately outputs the inputted data. That is, the write verify buffer 223 does not output the inputted read data but stores the inputted data therein using a FIFO method during the error correction time tECC. The write verify buffer 223 outputs the read data RD_Data at high speed, which data have been accumulated during the time the error vector Err is generated. When the outputting of the accumulated read data RD_Data is completed, the write verily buffer 223 serves as a general buffer. That is, the write verify buffer 223 outputs inputted data immediately.

The error-corrected read data RD_ECC are delivered into the host 230 through a host interface 224. The host 230 requests the flash memory device 210 to read data therefrom. The host 230 may be a computer system or a mobile device.

A high-capacity device is required to store the read data when detecting an error by using a FIFO method without outputting. To support this buffering method, there is a limitation in a conventional buffer memory. During an error correction operation, the write verify buffer 223 stores the read data RD_Data from the flash memory device 210 therein. The write verify buffer 223 stores the data that will be programmed in the flash memory device 210, and the data that will be reprogrammed. when a program failure occurs. Accordingly, the write verify buffer 223 has a storage capacity sufficient for stacking the read data RD_Data from the flash memory device 210 using a FIFO method during an error correction operation. In exemplary embodiments of the present invention, the write verify buffer 223 stores the read data RD_Data from the flash memory device 210 during an error correction operation. The scope of the present invention is not limited to this, however. That is, any means that can continuously store the read data in the memory controller 220 may be used during an error correction operation of the low-performance ECC block 222, which does not support an On-the-fly method. When an error correction is completed, the means promptly can output the stored read data.

Although not illustrated in the drawings, the memory control unit 225 receives an error detection result from the ECC block 222. The memory control unit 225 selects a buffering operation mode of the write verify buffer 223 according to the error detection result. That is, the memory control unit 225 controls the write verify buffer 223 to operate in one of a FIFO buffering mode and a general buffering mode. The data delay due to the error detection may occur according to a method of controlling the write verify buffer 223 of the control unit 223. It is apparent to those of ordinary skill in the art that the memory control unit 225 controls the write verify buffer 223, the flash interface 221, and the host interface 224. Moreover, the write verify buffer 223 can operate according to a control of the memory control unit 225 in one of a buffering mode that stores data by using a FIFO method and a general buffering mode that immediately outputs inputted data.

In the memory controller that does not support an error correction function using an On-the-fly method, a temporary operation halt of the memory controller 220 can he prevented by using the write verify buffer 223. Accordingly, the memory controller 220 continuously receives data from the flash memory device 210 while detecting an error and performing an error correction operation. The memory controller 220 in exemplar) embodiments of the present invention minimizes influence for a FTL function such as an address mapping function and a garbage collection function. An overall performance of the memory device may improve through modification of the read method.

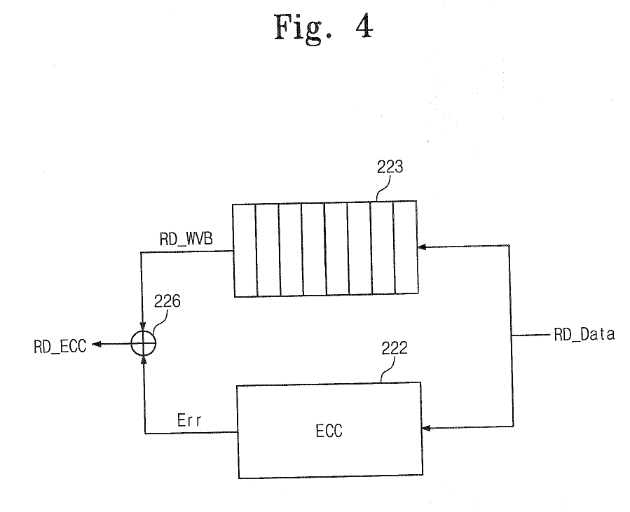

FIG. 4 is a block diagram illustrating a buffering operation of the write verify buffer 223 of FIG. 3. Referring to FIG. 4, the write verify buffer 223 and the ECC block 222 receive read data RD_Data simultaneously. A data transmission speed from the flash memory device 210 to the memory controller 220 is slower than a data processing speed in the memory controller 220. For example, one byte of data is transmitted during 30 ns in tire flash memory device 210, and two to four bytes of data are transmitted in the memory controller 220 during 30 ns. Accordingly, before detecting the error, the read data RD_Data inputted in the write verify buffer 223 are immediately outputted as data RD_WVB and then delivered into the host 230. On the other hand, when errors are detected by the ECC block 222, the write verify buffer 223 stores the data having errors and the subsequent read data RD_Data therein until an error correction operation is completed. When an error vector Err is generated according to an error correction operation, the write verify buffer 223 synchronizes the data having errors with the error vector Err for outputting. Then, the write verify buffer 223 outputs its stored data at high speed.

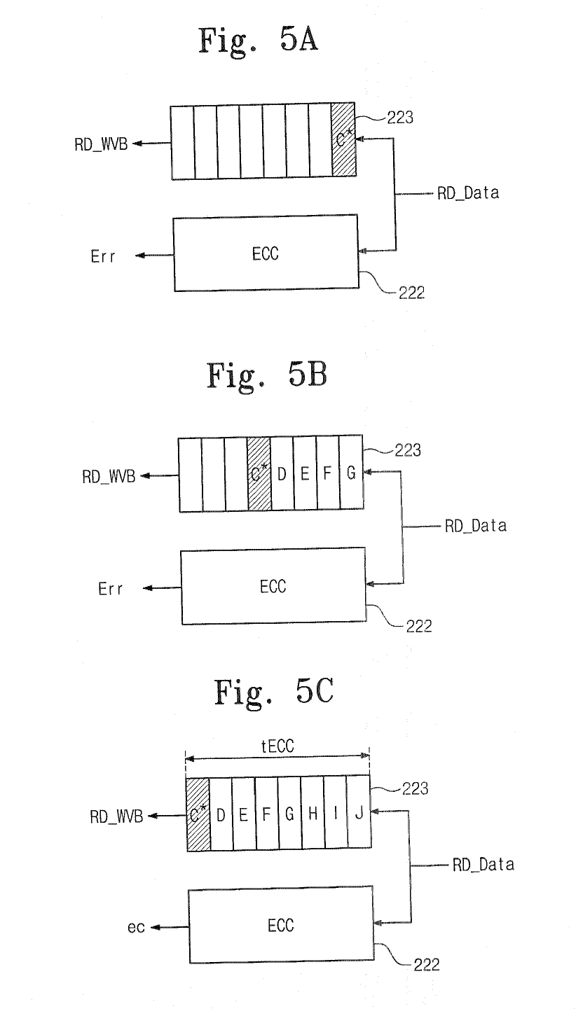

FIGS. 5A, 58, and 5C are block diagrams illustrating a FIFO operation of the write verify buffer 223. FIG. 5A is a block diagram of when data C* including errors are delivered into the write verify buffer 223 and the ECC block 222. At this point, the ECC block 222 generates a syndrome to determine whether there are errors or not in the data. When there is an error, the ECC block 222 notifies the memory control unit 225 of FIG. 3 of the error.

FIG. 5B is a block diagram of a FIFO buffering operation for the read data RD_Data delivered from the flash memory device 210. Until the ECC block 222 completes the error correction operation, the write verify buffer 223 stores the data C* and the subsequent read data without outputting.

FIG. 5C illustrates the state when the error correction operation is completed. According to the error correction operation, the ECC block 222 generates and outputs an error vector e_{c}, shown as ERR in FIG. 3, that can be used to correct the errors in the data C*. The output of the write verify buffer 223 is synchronized with the output of the error vector e_{c} and then immediately outputs the stored data by prioritizing the data C* including errors, in this exemplary embodiment, each data (for example, data D) may be a page unit or a sector unit.

According to the FIFO buffering operation of the write verify buffer 223 as illustrated in FIGS. 5A through 5C, the write verify buffer 223 servers as a general buffer that immediately outputs the inputted data when there is no error. When, an error is detected by the ECC block 222, however, the write verify buffer 223 stores the data having errors and the subsequent read data RD_Data from the flash memory device therein, by using a FIFO method. When the error correction operation is completed by the ECC block 222, the write verify buffer 223 immediately outputs the stored data at an outputable maximum speed.

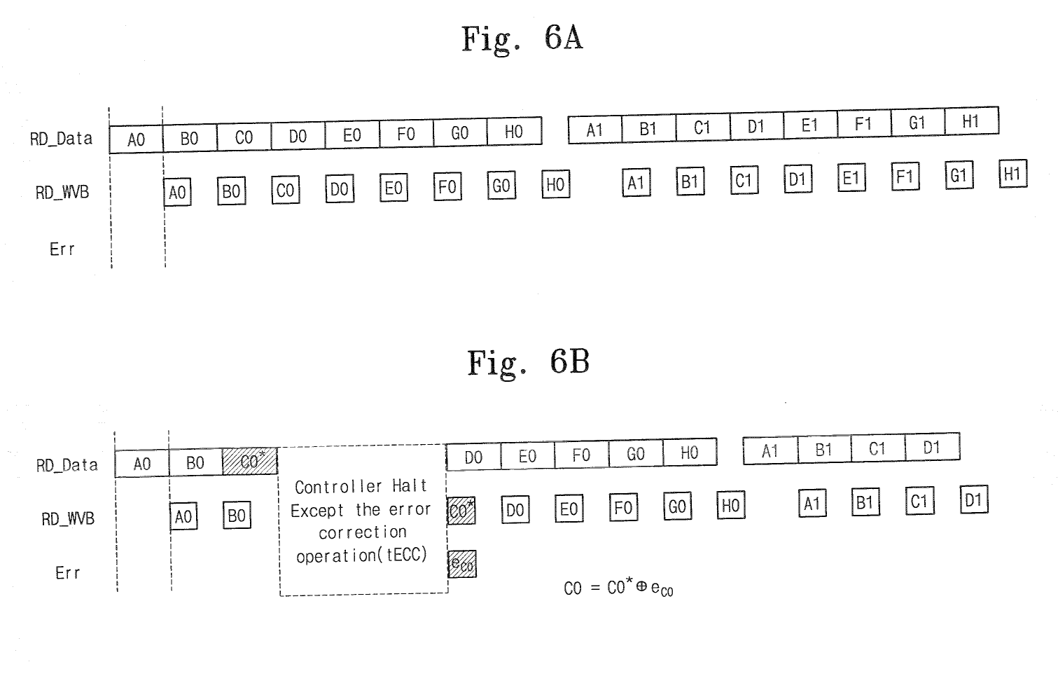

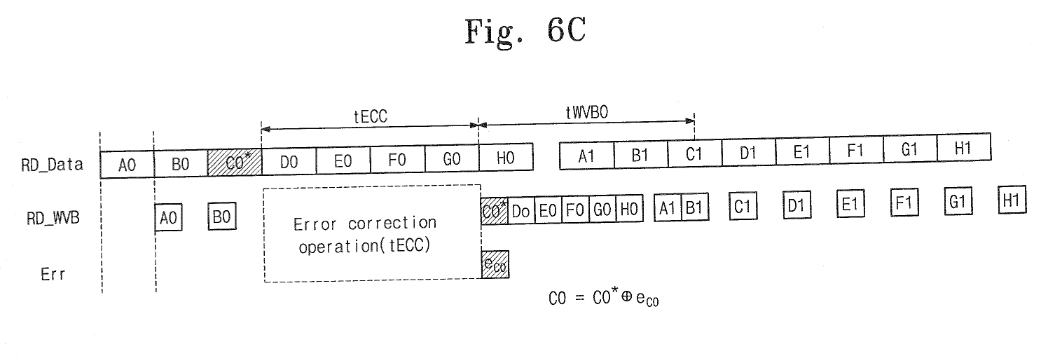

FIG. 6A is a timing diagram of data that are delivered and generated according to a read method in an exemplary embodiment of the present invention when there is no error in the data. Referring to FIG. 6A, the read data RD_Data are simultaneously Inputted into the ECC block 222 and the write verify buffer 223. When there is no error, the ECC block 222 does not generate an error vector Err. The write verify buffer 223 outputs the inputted read data RD_Data as data RD_WVB, as shown in FIG. 4. The data RD_WVB are outputted by a clock that is shorter than that of the read data RD_Data from the flash memory device 210. Thus, a high-speed outputting is possible. FIG. 6A illustrates these conditions.

FIG. 6B is a timing diagram of the ECC block 222 that does not support an On-the-fly method and does not use the write verify buffer 223 as the read FIFO buffer. FIG. 6B illustrates data C0* having an error among read data RD_Data under the above conditions. To perform an error correction operation, the memory controller 220 needs to halt other operations in addition to receiving read data from the flash memory device 210. This requires various resources for the error correction operation in the memory controller 220. Accordingly, when detecting errors in the data C*, the data DO that comes after the data C* can not be stored in the memory controller 220. The halt of these operations is cancelled after an error correction time tECC for the error correction operation is completed. Consequently, the memory controller 220 can not receive the read data and can not perform other FTL functions during the error correction time tECC.

FIG. 6C is a timing diagram of a read data RD_Data according to a read method in an exemplary embodiment of the present invention. Referring to FIG. 6C, it is assumed that data C0* includes an error among the read data RD_Data. In this case, although it does not support an On-the-fly method, a write verify buffer 223 with a sufficient capacity is used to buffer the read data RD_Data by using a FIFO method during an error correction operation. The write verify buffer 223 stores the data C0* having errors and the subsequent read data therein. At this point, the error correction operation is performed in the ECC block 222 during an error correction time tECC. The memory controller 220 can receive the read data during the error correction time tECC, however, since the write verify buffer 223 is used as a read FIFO buffer. After the error correction operation is completed and an error vector e_{c0} is generated, the write verify buffer 223 outputs the read data at high speed, which are stored therein by using a FIFO method. This operation is illustrated in a time interval tWVB0. The write verify buffer 223 may output the read data at a speed faster than a transmission speed from the flash memory device 210 to the write verify buffer 223. Accordingly, the write verify buffer 223 outputs an error correction time tECC and all data (for example, from C0 to B1) that are stored after the error correction time tECC into an XOR gate 226 at high speed. Among the data stored in the write verify buffer 223, the first outputted data is the data C0* having errors. In the XOR gate 226, the data C0* having errors are merged with the error vector e_{c0}. When a time tWVB0 elapses, the write verify buffer 223 completes the output of the read data therein. Next, the write verify buffer 223 serves as a conventional buffer that immediately outputs the read data from the flash memory device.

According to the operations of the exemplary embodiment of the present invention illustrated in FIGS. 6A through 6C, the memory controller 220 having the ECC block 222, which cannot support a low-performance On-the-fly function, can minimize the data delay during an error correction operation.

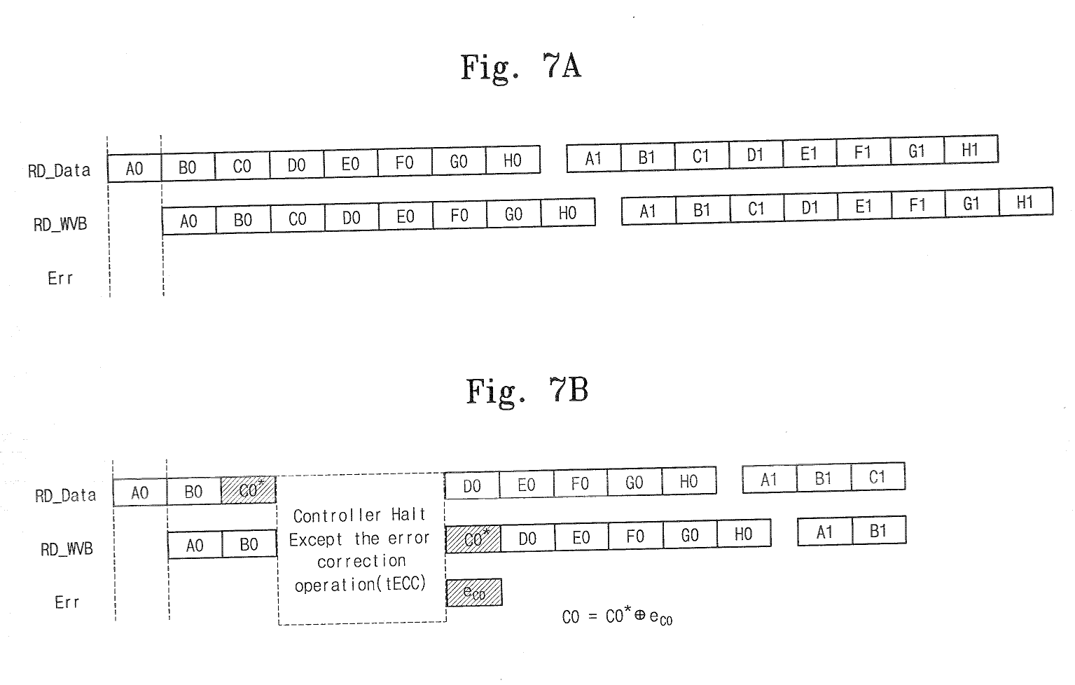

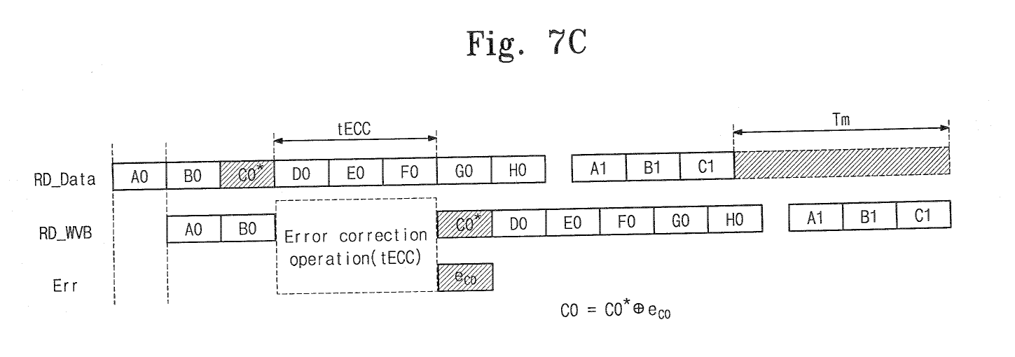

FIGS. 7A through 7C illustrate the effectiveness of the exemplary embodiment of the present invention under the assumption that an internal data processing speed of the memory controller 220 is similar to a read speed of the flash memory device 210.

FIG. 7A illustrates read data RD_Data read from the flash memory device and buffering data from the write verify buffer 223 when there is no error in the read data RD_Data. It is assumed that the read data RD_Data inputted into and the buffering data RD_WVB outputted from the write verify buffer 223 have a one cycle delay. At this point, since there is no error, the ECC block 22 does not generate an error vector Err.

FIG. 7B is a timing diagram when a read FIFO buffer is not utilized by the ECC block 222 that does not support an On-the-fly method. Referring to FIG. 7B, when the data C0* having errors are provided into the ECC block 222, the memory controller 220 can not receive the read data from the flash memory device 210 any more during an error correction time tECC. The memory controller 220 receives the read data RD_Data from the flash memory device 210 after the error vector e_{c0} of the ECC block 222 is outputted. Accordingly, when an error vector e_{c0} can not be calculated at high speed, the read data RD_Data of the flash memory device 210 is delayed by a predetermined time before being delivered into the memory controller 220.

FIG. 7C is a timing diagram illustrating an operation of the memory controller 220 that uses the write verify buffer 223 as a read FIFO buffer. It is assumed that data C0* among the read data RD_Data includes an error. In this case, a write verify buffer 223 that has a storage capacity sufficient for buffering the read data RD_Data by using a FIFO method during an error correction time tECC, is also used as a read FIFO buffer. The write verify buffer 223 stores the data C0* having errors and the subsequent read data therein. At this point, an error correction operation progresses during an error correction time tECC in the ECC block 222. Because the write verify buffer 223 is used as the read FIFO buffer, however, the memory controller 220 can receive the read data RD_Data during an error correction time tECC. When the error correction operation is completed and the error vector e_{c0} is generated, the write verify buffer 223 outputs the data C0* and the read data that are stored by using a FIFO method. The write verify buffer 223 outputs the read data when the error correction time tECC elapses. Although the data processing speed of the memory controller 220 is slow, it can receive data from the flash memory device 210 while detecting an error. Accordingly, the memory controller 220 may have spare time after receiving data C1. During this interval Tm, resources for other operations (for example, the FTL function) can be provided.

According to a read method of the flash memory device, there is provided a memory controller including a relatively low-performance error correction circuit that minimizes data delay when there is an error.

The above-disclosed subject matter is to be considered illustrative, and not restrictive, and the appended claims are intended to cover all such modifications, enhancements, and other exemplary embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of transmitting data from a flash memory device to a host, the method comprising:
detecting whether the data includes an error or not;
performing an error correction operation for correcting the data having the error when the error is detected to exist in the data; and
sequentially storing the data having the error and a plurality of subsequent read data without outputting,
wherein the storing of the data is performed, during the performing of the error correction operation.

2. The method of claim 1, wherein the butter stores the data having the error and the plurality of subsequent read data by using a FIFO method during the storing of the data.

3. The method of claim 1, wherein the buffer is a write verify buffer used for program verification when the data is programmed into the flash memory device.

4. The method of claim 1, wherein the error correction operation is not performed when there is no error detected in the data during the step of detecting.

5. The method of claim 4, wherein the buffer does not store the data therein but outputs the data.

6. The method of claim 1, further comprising sequentially outputting the stored data having the error and the plurality of subsequent read data in the butter as soon as the performing of the error correction operation is completed.

7. The method of claim 6, wherein the error in the data is removed by an error correction vector generated by the error correction operation.

8. The method of claim 1, wherein the error correction operation does not support an On-the-fly method.

9. A memory system comprising:
a flash memory device; and
a memory controller receiving read data from the flash memory device to detect whether the read data includes an error or not during a read operation, wherein
the memory controller stores the read data having the error and a plurality of subsequent read data therein during an error correction time therefor when the read data includes the error; and wherein
the memory controller removes the error in the read data by using an error vector generated during the error correction time.

10. The memory system of claim 9, wherein the memory controller comprises a buffer storing the read data having the error and the plurality of subsequent read data by using a FIFO (First In-First Out) method during the error correction time.

11. The memory system of claim 10, wherein the buffer outputs the data having the error first according to an inputted priority when the error correction time is completed.

12. The memory system of claim 11, wherein the buffer is a write verify buffer storing program data and re-supplying the program data when a program failure occurs during a program operation, of the flash memory device.

13. The memory system of claim 11, wherein the memory controller comprises an error correction block detecting the read data to determine whether the read data includes an error or not, and generating an error vector for correcting the error in the read data.

14. The memory system of claim 13, wherein the error vector merges with the read data having the error to remove the error, the read data being outputted from die buffer.

15. The memory system of claim 13, wherein the memory controller has a data processing speed faster than a read data transmission speed of the flash memory device.

16. The memory system of claim 9, wherein the memory controller does not support an error correction operation using an On-the-fly method.

17. A memory system comprising:
a flash memory device;
an error correction block detecting an error in read data of the flash memory device, and generating an error vector to correct the error in the read data;
a buffer selecting one of a first buffering mode and a second buffering mode, the first buffering mode receiving and outputting the read data simultaneously, the second buffering mode storing the read data by using a FIFO method without outputting: and
a control unit controlling the buffer to store the read data according to one of the first buffering mode and the second buffering mode in response to an error detection result from the error correction block during a read operation.

18. The memory system of claim 17, wherein the control, unit controls the buffer to store the read data according to the second buffering mode in response to an error detected result from the error correction block.

19. The memory system of claim 18, wherein the control unit controls the buffer to store the read data according to the first buffering mode in response to a non-error detected result from the error correction block.

20. The memory system of claim 19, wherein, when the read data is stored in the buffer according to the second buffering mode, the buffer stores the read data having the error and subsequent read data by using a FIFO method without outputting while the error correction block performs an error correction operation.

21. The memory system of claim 20, wherein the second buffering mode sequentially outputs the read data having the error first and the subsequent read data therein when the error correction operation is completed.

22. The memory system of claim 21, wherein the second buffering mode sequentially outputs the read data having the error first and the subsequent read data therein when the error correction operation is completed, and also outputs the read data at speed faster than a transmission speed from the flash memory device.

23. The memory system of claim 17, wherein an error correction time for generating the error vector of the error correction block is longer than one clock during which the buffer outputs the read data.

24. The memory system of claim 23, wherein the buffer comprises a buffer capacity sufficient for storing the read data having the error and the subsequent read data by using a FIFO method during the error correction time.

25. The memory system, of claim 24, wherein the buffer is a write verify buffer storing program data and re-supplying the program data when a program failure occurs during a program operation of the flash memory device.

26. The memory system of claim 17, further comprising an operator merging the error vector from the error correction block with the read data having the error from the buffer to remove the error.

27. The memory system of claim 26, wherein the operator performs an. XOR operation with the error vector and the read data having the error.

28. The memory system of claim 17, wherein the flash memory device is a NAND-type flash memory.
